(19) United States
(12) Patent Application Publication
(10) Pub. No.: US 2023/0359914 A1
(43) Pub. Date: Nov. 9, 2023

(54) METHOD FOR SUPERCONDUCTING QUANTUM CHIP

(71) Applicant: BEIJING BAIDU NETCOM SCIENCE TECHNOLOGY CO., LTD., BEIJING (CN)

(72) Inventors: Peng JIA, BEIJING (CN); Zhengyi CUI, BEIJING (CN); Lijing JIN, BEIJING (CN)

(21) Appl. No.: 18/222,877

(22) Filed: Jul. 17, 2023

(30) Foreign Application Priority Data
Jul. 22, 2022 (CN) 202210871473.3

(51) Int. Cl. G06N 10/20; G06N 10/40; G06F 30/20

(52) U.S. Cl. CPC G06N 10/20; G06N 10/40; G06F 30/20

(57) ABSTRACT

A method is provided that includes: determining a frequency range of a reading device, and corresponding quality factors of reading cavities and filters; determining frequency ranges of the reading cavities and filters based on the frequency range of the reading device; determining a frequency of each reading cavity and filter based on the frequency ranges of the reading cavity and filter and the corresponding quality factors; determining a length of each reading cavity and a length of each filter respectively, such that a difference value between its frequency and a determined frequency does not exceed a first threshold; determining a spacing and a coupling length between the reading cavities and the filters to make it close to a preset quality factor; and performing simulation verification on a layout of a superconducting quantum chip based on the lengths, spacing and coupling length of the reading cavities and the filters.

### CROSS REFERENCE TO RELATED APPLICATIONS

The present application claims priority to Chinese Patent Application No. 202210871473.3 filed on Jul. 22, 2022, the contents of which is hereby incorporated by reference in its entirety for all purposes.

### TECHNICAL FIELD

The present disclosure relates to the field of quantum computers, in particular the technical field of superconducting quantum chips, and specifically relates to a superconducting quantum chip design method and apparatus, an electronic device, a computer readable storage medium and a computer program product.

### BACKGROUND

In recent years, with continuous updating and iteration of a chip manufacturing procedure, a traditional chip has entered a “post-Moore era” from a “Moore era”, and its computing power reaches a bottleneck. Quantum computation, relying on its unique characteristics, can break through constraints of the manufacturing procedure on the computation power to become a focus of academic and industrial research. Compared with traditional computation, quantum computation has significant advantages in dealing with complex quantum system problems. In addition, quantum computation is also of great significance in frontier scientific research fields such as artificial intelligence, quantum chemistry, and biopharmaceutics. Research and development of high-potential quantum applications greatly promote the development of quantum hardware. After decades of exploration, physical realization modes of quantum computation hardware mainly include various technical routes such as an ion trap, a light quantum, and a superconducting circuit. Among them, the superconducting circuit is easier to expand than other systems, is easier to scale up with mature micro-nano processing technology, and is considered to be a technical solution most possible to first realize practical quantum computation.

### SUMMARY

The present disclosure provides a superconducting quantum chip design method and apparatus, an electronic device, a computer readable storage medium and a computer program product.

According to one aspect of the present disclosure, a method for designing a superconducting quantum chip is provided. the method comprising: determining a frequency range of a reading device, a first quality factor corresponds to a first number of reading cavities, and a second quality factor corresponds to the first number of filters, wherein the superconducting quantum chip comprises a reading line, the first number of quantum bits corresponds to the reading line, the first number of reading cavities, and a first number of filters, wherein each quantum bit of the first number of quantum bits corresponds to a pair of a reading cavity and a filter, and wherein the reading device is configured to perform a reading operation on the first number of quantum bits through the reading line; determining a first frequency range corresponding to the first number of reading cavities and a second frequency range corresponding to the first number of filters based on the frequency range of the reading device; determining a frequency of each reading cavity of the first number of reading cavities based on the first frequency range and the first quality factor; determining a frequency of each filter of the first number of filters based on the second frequency range and the second quality factor; determining a length of each reading cavity of the first number of reading cavities and a length of each filter of the first number of filters, respectively, wherein a frequency difference between a frequency of each reading cavity and a corresponding frequency determined based on the first frequency range and the first quality factor and a frequency difference between a frequency of each filter and a corresponding frequency determined based on the second frequency range and the second quality factor do not exceed a first threshold; for each quantum bit of the first number of quantum bits, determining a spacing and a coupling length between the pair of the reading cavity and the filter corresponding to the quantum bit in such a manner that a difference value between a quality factor of the reading cavity and the first quality factor does not exceed a second threshold and a difference value between a quality factor of the filter and the second quality factor does not exceed a third threshold; and performing a simulation verification on a layout of the superconducting quantum chip based on the determined respective lengths of the reading cavities in the first number of reading cavities, the determined respective lengths of the filters in the first number of filters, and the determined respective spacing and coupling length between the pair of the reading cavity and the filter corresponding to each quantum bit.

According to another aspect of the present disclosure, an electronic device for designing a superconducting quantum chip is provided, wherein the electronic device including: a memory storing one or more programs configured to be executed by one or more processors, the one or more programs including instructions for causing the electronic device to perform operations comprising: determining a frequency range of a reading device, a first quality factor corresponds to a first number of reading cavities, and a second quality factor corresponds to the first number of filters, wherein the superconducting quantum chip comprises a reading line, the first number of quantum bits corresponds to the reading line, the first number of reading cavities, and a first number of filters, wherein each quantum bit of the first number of quantum bits corresponds to a pair of a reading cavity and a filter, and wherein the reading device is configured to perform a reading operation on the first number of quantum bits through the reading line; determining a first frequency range corresponding to the first number of reading cavities and a second frequency range corresponding to the first number of filters based on the frequency range of the reading device; determining a frequency of each reading cavity of the first number of reading cavities based on the first frequency range and the first quality factor; determining a frequency of each filter of the first number of filters based on the second frequency range and the second quality factor; determining a length of each reading cavity of the first number of reading cavities and a length of each filter of the first number of filters, respectively, wherein a frequency difference between a frequency of each reading cavity and a corresponding frequency determined based on the first frequency range and the first quality factor and a frequency difference between a frequency of each filter and a corresponding frequency determined based on the second frequency range and the second quality facto do not exceed a first threshold; for each quantum bit of the first number of quantum bits, determining a spacing and a coupling length between the pair of the reading cavity and the filter corresponding to the quantum bit in such a manner that a difference value between a quality factor of the reading cavity and the first quality factor does not exceed a second threshold and a difference value between a quality factor of the filter and the second quality factor does not exceed a third threshold; and performing a simulation verification on a layout of the superconducting quantum chip based on the determined respective lengths of the reading cavities in the first number of reading cavities, the determined respective lengths of the filters in the first number of filters, and the determined respective spacing and coupling length between the pair of the reading cavity and the filter corresponding to each quantum bit.

According to another aspect of the present disclosure, a non-transitory computer-readable storage medium that stores one or more programs is provided, wherein the one or more programs comprising instructions that, when executed by one or more processors of a computing device, cause the computing device to implement operations comprising: determining a frequency range of a reading device, a first quality factor corresponds to a first number of reading cavities, and a second quality factor corresponds to the first number of filters, wherein the superconducting quantum chip comprises a reading line, the first number of quantum bits corresponds to the reading line, the first number of reading cavities, and a first number of filters, wherein each quantum bit of the first number of quantum bits corresponds to a pair of a reading cavity and a filter, and wherein the reading device is configured to perform a reading operation on the first number of quantum bits through the reading line; determining a first frequency range corresponding to the first number of reading cavities and a second frequency range corresponding to the first number of filters based on the frequency range of the reading device; determining a frequency of each reading cavity of the first number of reading cavities based on the first frequency range and the first quality factor; determining a frequency of each filter of the first number of filters based on the second frequency range and the second quality factor; determining a length of each reading cavity of the first number of reading cavities and a length of each filter of the first number of filters, respectively, wherein a frequency difference between a frequency of each reading cavity and a corresponding frequency determined based on the first frequency range and the first quality factor and a frequency difference between a frequency of each filter and a corresponding frequency determined based on the second frequency range and the second quality factor do not exceed a first threshold; for each quantum bit of the first number of quantum bits, determining a spacing and a coupling length between the pair of the reading cavity and the filter corresponding to the quantum bit in such a manner that a difference value between a quality factor of the reading cavity and the first quality factor does not exceed a second threshold and a difference value between a quality factor of the filter and the second quality factor does not exceed a third threshold; and performing a simulation verification on a layout of the superconducting quantum chip based on the determined respective lengths of the reading cavities in the first number of reading cavities, the determined respective lengths of the filters in the first number of filters, and the determined respective spacing and coupling length between the pair of the reading cavity and the filter corresponding to each quantum bit.

It should be understood that the content described in this part is not intended to identify key or important features of the embodiments of the present disclosure, and is not used to limit the scope of the present disclosure as well. Other features of the present disclosure will become easily understood through the following specification.

### BRIEF DESCRIPTION OF THE DRAWINGS

Accompanying drawings show the embodiments as examples, constitute a part of the specification, and together with text description of the specification, serve to explain exemplary implementations of the embodiments. The shown embodiments are only for the purpose of illustration, and do not limit the scope of the claims. In all the accompanying drawings, the same reference numerals refer to the similar but not necessarily the same elements.

FIG. 1 shows a flow diagram of a superconducting quantum chip design method according to an embodiment of the present disclosure;

FIG. 2A and FIG. 2B respectively show a schematic diagram of a variation relationship of respective frequency of a reading cavity and a filter with a length according to an embodiment of the present disclosure;

FIG. 3 shows a schematic diagram of a pair of reading cavity and filter according to an embodiment of the present disclosure;

FIG. 4 shows a flow diagram of a superconducting quantum chip manufacturing method according to an embodiment of the present disclosure;

FIG. 5 shows a structural block diagram of a superconducting quantum chip design apparatus according to an embodiment of the present disclosure;

FIG. 6 shows a structural block diagram of a superconducting quantum chip manufacturing apparatus according to an embodiment of the present disclosure; and

FIG. 7 shows a structural block diagram of an exemplary electronic device capable of being used for implementing an embodiment of the present disclosure.

### DETAILED DESCRIPTION

The exemplary embodiments of the present disclosure are illustrated below with reference to the accompanying drawings, including various details of the embodiment of the present disclosure for aiding understanding, and they should be regarded as being only exemplary. Therefore, those ordinarily skilled in the art should realize that various changes and modifications may be made on the embodiments described here without departing from the scope of the present disclosure. Similarly, for clarity and simplicity, the following description omits description of a publicly known function and structure.

In the present disclosure, unless otherwise noted, describing of various elements by using terms “first”, “second” and the like does not intend to limit a position relationship, a time sequence relationship or an importance relationship of these elements, and this kind of terms is only used to distinguish one component from another component. In some examples, a first element and a second element may refer to the same instance of this element, while in certain cases, they may also refer to different instances based on the contextual description.

The terms used in description of various examples in the present disclosure are only for the purpose of describing the specific examples, and are not intended to limit them. Unless otherwise explicitly indicated in the context, if the quantity of the elements is not limited specially, there may be one or more elements. In addition, the term “and/or” used in the present disclosure covers any one of and all possible combination modes in the listed items.

An embodiment of the present disclosure will be described below in detail with reference to the accompanying drawings.

So far, various different types of computers in use take classical physics as the theoretical basis of information processing, called traditional computers or classical computers. A classical information system uses binary data bits that are the most easily realized in physics to store data or a program. Each binary data bit is represented by 0 or 1, called a bit, as the smallest information unit. There are inevitable weaknesses in a classical computer itself. The first is the most basic limitation of energy consumption in a computation process. Minimum energy required by a logic element or a storing unit shall be more than several times of kT to avoid misoperation under thermal expansion and falling. The second is information entropy and heating energy consumption. The third is that when a wiring density of computer chips is very high, according to a Heisenberg uncertainty relationship, uncertainty of momentum will be very large when uncertainty of an electron position is very small. Electrons are no longer bound, and there will be a quantum interference effect, which will even destroy the performance of the chip.

A quantum computer is a kind of physical device that follows properties and laws of quantum mechanics to perform high-speed mathematical and logical operations, and store and process quantum information. When a certain device processes and computes quantum information and runs a quantum algorithm, it is the quantum computer. The quantum computer follows the unique laws of quantum dynamics (especially quantum interference) to realize a new mode of information processing. For parallel processing of computation problems, the quantum computer has an absolute advantage over the classical computer in speed. Transformation realized by the quantum computer for each superimposed component is equivalent to a classical computation. All these classical computations are completed at the same time, and are superimposed according to a certain probability amplitude to give an output result of the quantum computer. This kind of computation is called quantum parallel computation. Quantum parallel processing has greatly improved the efficiency of the quantum computer, making it possible to complete the work that the classical computer cannot do, such as factorization of a very large natural number. Quantum coherence has been essentially utilized in all quantum ultrafast algorithms. Therefore, quantum parallel computation using a quantum state instead of a classical state can achieve an operation speed and information processing function incomparable with the classical computer, and saves a lot of computing resources at the same time.

As a most core part of the quantum computer, a quantum chip is a hardware apparatus that executes quantum computation and quantum information processing. In recent years, scholars at home and abroad have carried out a lot of research work on a superconducting quantum chip based on a superconducting circuit. Google has developed a superconducting quantum chip with 53 quantum bits and announced the realization of “quantum supremacy”. IBM recently announced the research and development of a superconducting quantum chip with 127 quantum bits. It can be seen that the research and development of the superconducting quantum chip has become a core technology in the field of quantum computation. With the progress of a micro-nano processing technology, scale integration of the quantum bits is also a future development direction of the quantum chip. With the increase of the number of the quantum bits, the design difficulty of the quantum chip will increase accordingly.

The design of a superconducting quantum chip mainly includes the design of component parameters and integrated positions of the quantum bits, a reading cavity, a filter, a reading line, a control line and the like in the chip. As a core part of the superconducting quantum chip, the design process of the quantum bits will take into account many factors such as configuration, and electromagnetic parameters. The reading cavity and the filter are different from the quantum bits, and there are many of them in the design process. The design parameters have certain regularity and flow. At present, in the field of quantum chip design, there are two main modes to design the reading cavity and the filter. One is filter-free design, which ensures that each quantum bit has one reading cavity for coupling, and uses the reading line to couple with the plurality of reading cavities. Although the design flow is simple, there are problems such as slow reading speed and crosstalk in the structure. The second is to design the plurality of reading cavities to couple with the single filter. This design adds a variable impedance filter on the basis of the reading cavity, which can solve the problem of crosstalk, thus realizing the requirement of fast measurement of the quantum bits. However, a simulation iteration process of the variable impedance filter is complex, and the design is difficult.

Therefore, according to an embodiment of the present disclosure, a superconducting quantum chip design method is provided. A superconducting quantum chip includes a reading line, a first number of quantum bits corresponding to the reading line, and pairs of reading cavities and filters respectively corresponding to the quantum bits.

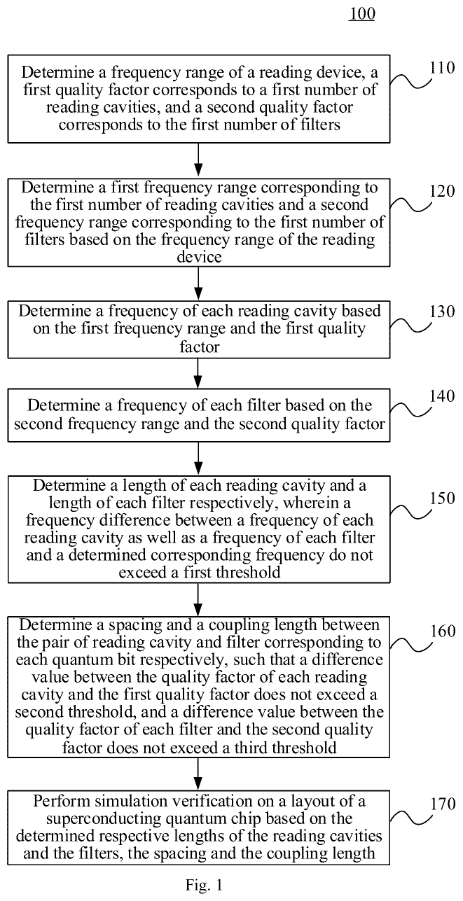

FIG. 1 shows a flow diagram of the superconducting quantum chip design method according to an embodiment of the present disclosure. As shown in FIG. 1, the method 100 includes: determine a frequency range of a reading device, a first quality factor corresponds to a first number of reading cavities, and a second quality factor corresponds to the first number of filters, wherein the superconducting quantum chip comprises a reading line, the first number of quantum bits corresponds to the reading line, the first number of reading cavities, and a first number of filters, wherein each quantum bit of the first number of quantum bits corresponds to a pair of a reading cavity and a filter, and wherein the reading device is configured to perform a reading operation on the first number of quantum bits through the reading line (step 110); determine a first frequency range corresponding to the first number of reading cavities and a second frequency range corresponding to the first number of filters based on the frequency range of the reading device (step 120); determine a frequency of each reading cavity based on the first frequency range and the first quality factor (step 130); of the first number of reading cavities a frequency of each filter based on the second frequency range and the second quality factor (step 140); determine a length of each reading cavity and a length of each filter respectively, wherein a frequency difference between a frequency of each reading cavity and a corresponding frequency determined based on the first frequency range and the first quality factor and a frequency difference between a frequency of each filter and a corresponding frequency determined based on the second frequency range and the second quality factor do not exceed a first threshold (step 150); for each quantum bit of the first number of quantum bits, determine a spacing and a coupling length between the pair of the reading cavity and the filter corresponding to the quantum bit, such that a difference value between a quality factor of the reading cavity and the first quality factor does not exceed a second threshold, and a difference value between a quality factor of the filter and the second quality factor does not exceed a third threshold (step 160); and perform simulation verification on a layout of the superconducting quantum chip based on the determined respective lengths of the reading cavities in the first number of reading cavities, the determined respective lengths of the filters in the first number of filters, and the determined respective spacing and coupling length between the pair of the reading cavity and the filter corresponding to each quantum bit (step 170).

According to the embodiment of the present disclosure, all iteration nodes in an iteration operation have judgment basis and an iteration direction. If there is parameter modification in a chip simulation process, a modification node may be quickly determined and the iteration may continue, which improves fault tolerance of chip design.

In step 110, the frequency range of the reading device, the first quality factor corresponding to the first number of reading cavities, and the second quality factor corresponding to the first number of filters are determined.

In the present disclosure, some parameter values in the superconducting quantum chip may be determined in advance, including: the frequency range of the reading device, and the number of the required reading cavities and filters. The reading device is used for performing the reading operation on the first number of quantum bits through the reading line. As an example, the frequency range of the reading device may be set according to an actual test demand and device performance, and the number of the reading cavities and filters (i.e. the number of the quantum bits) may be set according to a layout structure and performance requirements of the superconducting quantum chip. The reading cavities and the filters are the same in number, which is the number of the quantum bits. Each quantum bit corresponds to one pair of reading cavity and filter. Therefore, after determining how many quantum bits need to be subjected to the reading operation through the reading line, how many sets of reading cavities and filters needed on the reading line may be determined.

In the present disclosure, a preset parameter value in the predetermined superconducting quantum chip may further include, for example, the reading frequency of the quantum bits, the respective quality factors (Q values) of the reading cavities and the filters, and the coupling strength between the quantum bits and the reading cavities.

In step 120, the first frequency range corresponding to the first number of reading cavities and the second frequency range corresponding to the first number of filters are determined based on the frequency range of the reading device.

According to some embodiments, determining the first frequency range corresponding to the first number of reading cavities and the second frequency range corresponding to the first number of filters includes: determining the first frequency range and the second frequency range, such that the first frequency range and the second frequency range are close to the frequency range of the reading device within a preset error range.

In some examples, an initial frequency range of the reading cavities and the filters may be determined according to the frequency range of the reading device. In the present disclosure, the reading cavities and the filters may be set to have the same frequency range, which are both close to the frequency range of the reading device. Specifically, at the beginning of the design of the superconducting quantum chip, the frequency range of the reading device may be predetermined as (wₘᵢₙ, wₘₐₓ)(unit: GHz). Considering that a system error existing in micro-nano processing will cause the frequency of the reading cavities to float up and down, for example, to float up and down in an error range of 0.5 GHz, the initial frequency range of the reading cavities and filters may be set to be: (wₘᵢₙ+0.5 GHz, wₘₐₓ−0.5 GHz).

According to some embodiments, determining the first frequency range corresponding to the first number of reading cavities and the second frequency range corresponding to the first number of filters includes: a preset coupling strength between the quantum bit and the reading cavity, and a reading frequency of the quantum bit are determined; and the first frequency range and the second frequency range are determined based on the coupling strength and the reading frequency.

In some examples, the frequency ranges of the reading cavities and the filters are determined according to the coupling strength between the quantum bits and the reading cavities, and the reading frequency of the quantum bits. Specifically, the reading frequency of the quantum bits is defined as: w_{q}, and the reading cavities need to meet a dispersion coupling condition with the quantum bits, namely

$$\frac{g}{{Δ}_{Q - CPW}} < a .$$

Where, a is a preset value and is 0.1; g is the coupling strength between the quantum bits and the reading cavities; and Δ_{Q-CPW} is a frequency difference between the quantum bits and the reading cavities. Exemplarily, when determining that the frequency range of reading cavities needs to meet Δ_{Q-CPW}≥1 GHz, for example, the first frequency range and the second frequency range may be further set to be (wₘᵢₙ+0.5 GHz, w_{q}−1 GHz) or (w_{q}+1 GHz, wₘₐₓ−0.5 GHz).

In step 130, the frequency of each reading cavity is determined based on the first frequency range and the first quality factor. In step 140, the frequency of each filter is determined based on the second frequency range and the second quality factor.

According to some embodiments, the superconducting quantum chip includes the plurality of quantum bits. Determining the frequency of each reading cavity includes: a frequency interval between the first number of reading cavities is respectively determined based on the first frequency range and the quality factor, so as to determine the frequency of each reading cavity based on the frequency interval between the first number of reading cavities. Determining the frequency of each filter includes: a frequency interval between the first number of filters is respectively determined based on the second frequency range and the quality factor, so as to determine the frequency of each filter based on the frequency interval between the first number of filters.

Specifically, the frequency of each reading cavity and filter may be allocated according to the number of the required reading cavities and filters and the quality factor (Q value). The number of quantum bits to be read on one reading line is determined, and thus the number of sets of reading cavities and filters to be designed on one reading line is determined. According to the different layout structure and performance requirements of the different superconducting quantum chips, n reading cavities and n filters are designed, so the frequency of each reading cavity and each filter needs to be allocated.

According to some embodiments, the frequency interval between the first number of reading cavities is greater than a maximum bandwidth (i.e. dissipation rate) of the first number of reading cavities, and the frequency interval between the first number of filters is greater than a maximum bandwidth (i.e. dissipation rate) of the first number of filters. In order to ensure the independence of a signal between the reading cavities on the reading line and reduce crosstalk, the frequency interval Δ_{CPQ} between the reading cavities and the bandwidth κ (i.e. dissipation rate) of the reading cavities meet Δ_{CPQ}>κ, and the filter is the same. Specifically, the bandwidth range may be determined according to a ratio of its corresponding frequency range to the corresponding Q value. Moreover, its corresponding frequency interval is set to be greater than its maximum bandwidth so as to reduce crosstalk.

Here, in one pair of reading cavity and filter, their respective frequencies may be equal, which is not limited here.

In step 150, a length of each reading cavity and a length of each filter are determined respectively, such that a frequency difference between a frequency of each reading cavity and a corresponding frequency determined based on the first frequency range and the first quality factor and a frequency difference between a frequency of each filter and a corresponding frequency determined based on the second frequency range and the second quality factor do not exceed a first threshold.

As described above, after determining the frequency of each reading cavity and filter, it is necessary to determine the respective lengths and relative positions of each pair of reading cavity and filter. The length of the device will affect its own frequency, and the relative position of the reading cavities and the filters will affect the coupling strength of the two devices. Specifically, in some examples, the corresponding requirements are met by performing simulation iteration on the reading cavities and the filters.

In some embodiments, a corresponding relationship between the respective lengths of the reading cavities and filters and their frequency (i.e. the bare frequency) is determined. Exemplarily, in order to save the time of a simulation process, simulation precision during bare frequency simulation is controlled within 10%, and the number of times of convergence is 2. It is concluded that an error between the bare frequency of the device and the frequency allocated above is within 0.1 GHz (equivalent to the frequency difference not exceeding the first threshold). The corresponding length of the device is found within the determined frequency range, and the corresponding relationship between the respective lengths of the reading cavities and the filters and their frequency is determined respectively.

In step 160, the spacing and the coupling length between the pair of reading cavity and filter corresponding to each quantum bit are determined respectively, such that the difference value between the quality factor of each reading cavity and the first quality factor does not exceed the second threshold, and the difference value between the quality factor of each filter and the second quality factor does not exceed the third threshold.

As described above, after the length of the reading cavities and the filters is initially determined, a distance and the coupling length between the two devices are adjusted iteratively to make the quality factor (Q value) and coupling strength (g) of the two devices meet a preset requirement. The second threshold may be equal to or not equal to the third threshold here, which is not limited here. Exemplarily, principles followed in the iterative process may include: 1) the smaller the interval between the reading cavity and the filter, the greater the coupling strength g; 2) the greater the coupling length between the two devices, the greater the coupling strength g; 3) the smaller the coupling strength g, the greater the quality factor Q; and 4) the size of micro-nano processing is considered, and the minimum distance between the two devices, for example, shall not be less than 3 μm.

It may be understood that the principles needing to be followed in the iterative process may be set according to the actual simulation demand. For example, based on the above principles, simulation iteration is performed on the reading cavity and the filter to determine the spacing and coupling length between the two devices.

In step 170, simulation verification is performed on a layout of the superconducting quantum chip based on the determined respective lengths of the reading cavities and the filters, the spacing and the coupling length.

According to some embodiments, performing simulation verification on the layout of the superconducting quantum chip based on the determined respective lengths of the reading cavities and the filters, the spacing and the coupling length includes: simulation verification is performed on the layout of the superconducting quantum chip to adjust the length of each reading cavity and the length of each filter, such that the frequency difference between the frequency of each reading cavity as well as the frequency of each filter and the determined corresponding frequency does not exceed a fourth threshold.

According to some embodiments, the fourth threshold is smaller than the first threshold.

Specifically, the lengths of the reading cavity and the filter are finely adjusted to determine their final dimensions. As described above, after step 160, each reading cavity and filter have a preliminary size and relative position and the corresponding bare frequency. The reading cavity and the filter are integrated with the quantum bits to form a relatively complete local layout of the four devices “quantum bit-reading cavity-filter-reading line”. Electromagnetic simulation continues to be performed on the basis of local layout. According to a high-precision simulation result of the reading cavity and filter frequency, the length fine-adjustment operation is performed iteratively. Exemplarily, if an error between the device simulation frequency after iteration and the frequency allocated by it is controlled within 0.05 GHz, the simulation precision converges to be about 1%, and the number of times of simulation convergence is 2, then it may be judged that the simulation design of the reading cavity and filter is completed.

According to the method described in the present disclosure, it may be widely applied in the simulation design of multi-bit superconducting quantum chips. Especially after the number of quantum bits in the chip layout increases, the method described in the present disclosure can greatly improve the efficiency of chip design, research and development.

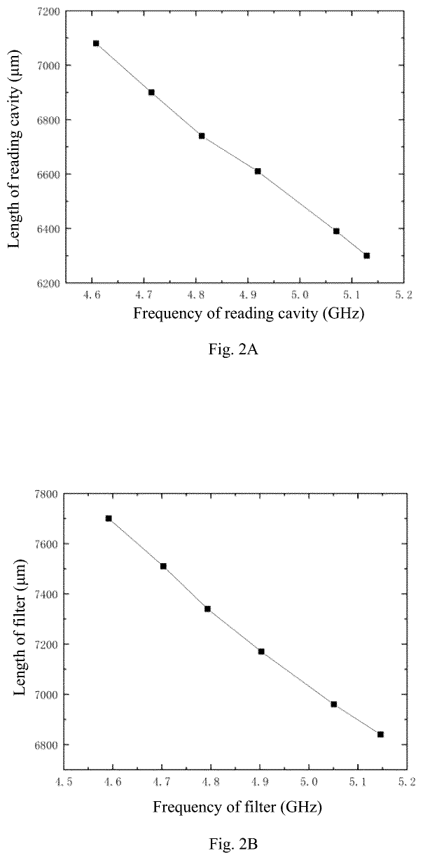

In order to verify the effect of the solution of the present disclosure, according to the method described in the present disclosure, the reading cavity and filter of the superconducting quantum chip with a 5×5 checkerboard layout are designed. Specifically, the frequency range of the reading device, the reading frequency of the quantum bits, the number of the required reading cavities and filters, and the corresponding Q value are determined first. For example, the frequency range of the reading device is 4-8 GHz, the reading frequency of the quantum bits is 6 GHz, the number of the required reading cavities and filters is 5 sets (on one reading line), and the quality factor Q values of the reading cavity and filter are 1000 and 100 respectively. Then the following operations are executed: the frequency ranges of the reading cavity and the filter are preliminarily determined as: 4.5-7.5 GHz; after the dispersion coupling condition is met between the reading cavity and the quantum bit, the frequency range is determined as: 4.5-5 GHz; the frequency allocated to one pair of reading cavity and filter is determined according to the number of required reading cavities and filters: 4.6, 4.7, 4.8, 4.9 and 5.0 (GHz); and simulation iteration is performed on the bare frequency of the reading cavity and the filter, with the simulation precision of 10%, and convergence is performed twice to determine a variation relationship of the device frequency with the length. FIG. 2A and FIG. 2B respectively show a schematic diagram of a variation relationship of respective frequency of the reading cavity and the filter with the length according to an embodiment of the present disclosure.

Through the iteration of electromagnetic simulation software, the corresponding relationship between the reading cavity/filter of each frequency and its length is preliminarily determined as shown in Table 1.

TABLE 1

| Target | | | Length | |
|---|---|---|---|---|
| frequency | | | of | |
| (bare | Reading | | reading | Length |
| frequency) | cavity | Filter | cavity | of filter |
| (GHz) | (GHz) | (GHz) | (μm) | (μm) |
| 4.6 | 4.60814 | 4.59175 | 7080 | 7700 |
| 4.7 | 4.71467 | 4.70331 | 6900 | 7510 |
| 4.8 | 4.81149 | 4.79344 | 6740 | 7340 |
| 4.9 | 4.91919 | 4.90315 | 6610 | 7170 |
| 5.0 | 5.07031 | 5.05093 | 6390 | 6960 |

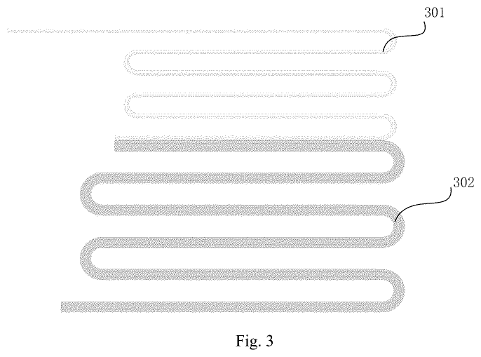

FIG. 3 shows a schematic diagram of one pair of reading cavity and filter according to an embodiment of the present disclosure. As shown in FIG. 3, a device 301 is the reading cavity and a device 302 is the filter (at this time, the spacing between the reading cavity and the filter is not obvious to the naked eye). By iteratively adjusting the spacing and coupling length between the two devices, the spacing is determined as 5 μm, and the coupling length is determined as 1200 μm. The corresponding relationship between the reading cavity/filter of each frequency and its corresponding Q value is shown in Table 2.

TABLE 2

| | | | Length of | | | Simulation |
|---|---|---|---|---|---|---|
| Target | Reading | | reading | Length of | Q value | convergence |
| frequency | cavity | Filter | cavity | filter | (reading | precision |
| (GHz) | (GHz) | (GHz) | (μm) | (μm) | cavity and filter) | (%) |
| 4.6 | 4.60814 | 4.59175 | 7080 | 7700 | (806.502, 96.1266) | 7.67 |
| 4.7 | 4.71467 | 4.70331 | 6900 | 7510 | (805.933, 93.8129) | 9.15 |
| 4.8 | 4.81149 | 4.79344 | 6740 | 7340 | (997.958, 91.9090) | 8.73 |
| 4.9 | 4.91919 | 4.90315 | 6610 | 7170 | (993.189, 87.8615) | 5.26 |
| 5.0 | 5.07031 | 5.05093 | 6390 | 6960 | (954.050, 81.2646) | 4.2 |

Finally, high-precision frequency simulation is performed on the above reading cavity and filter after layout confirmation, and the lengths of the reading cavity and filter are adjusted through iteration. The simulation precision is controlled at about 1%, and the number of times of convergence is 2. The final reading cavity/filter design result obtained through simulation is shown in Table 3.

TABLE 3

| | | | Length of | | | Simulation |
|---|---|---|---|---|---|---|
| Target | Reading | | reading | Length of | Q value | convergence |
| frequency | cavity | Filter | cavity | filter | (reading | precision |
| (GHz) | (GHz) | (GHz) | (μm) | (μm) | cavity and filter) | (%) |
| 4.6 | 4.60478 | 4.58398 | 7080 | 7710 | (1235.44, 152.852) | 2.24 |
| 4.7 | 4.71645 | 4.69883 | 6910 | 7510 | (1014.93, 148.592) | 1.8 |
| 4.8 | 4.81813 | 4.79522 | 6750 | 7340 | (1391.83, 128.966) | 1.9 |
| 4.9 | 4.91951 | 4.89758 | 6630 | 7190 | (1263.70, 131.100) | 1.8 |
| 5.0 | 4.98103 | 5.00020 | 6540 | 7040 | (1120.73, 126.390) | 1.5 |

According to the method described in the present disclosure, the simulation iteration work of the reading cavity and filter in superconducting quantum chip with the 5X5 checkerboard layout is completed. It can be seen that if the parameters of the reading cavity and filter need to be adjusted subsequently, the corresponding modification measures and iteration basis can be found quickly in the process, which improves the design efficiency of the superconducting quantum chip and has guiding significance for the scale design, simulation and iteration of the superconducting quantum chip.

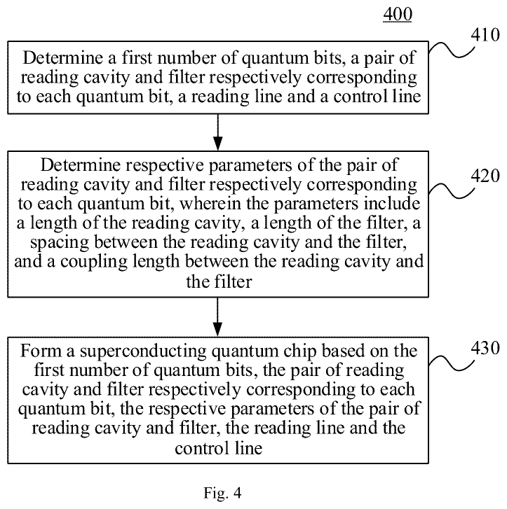

According to an embodiment of the present disclosure, as shown in FIG. 4, a superconducting quantum chip manufacturing method 400 is further provided, including: a first number of quantum bits, a pair of reading cavity and filter respectively corresponding to each quantum bit, a reading line and a control line are determined (step 410); respective parameters of the pair of reading cavity and filter respectively corresponding to each quantum bit are determined, wherein the parameters include a length of the reading cavity, a length of the filter, a spacing between the reading cavity and the filter, and a coupling length between the reading cavity and the filter (step 420); and a superconducting quantum chip is formed based on the first number of quantum bits, the pair of reading cavity and filter respectively corresponding to each quantum bit, the respective parameters of the pair of reading cavity and filter, the reading line and the control line (step 430). The parameters are determined according to the method described in any one of the above embodiments.

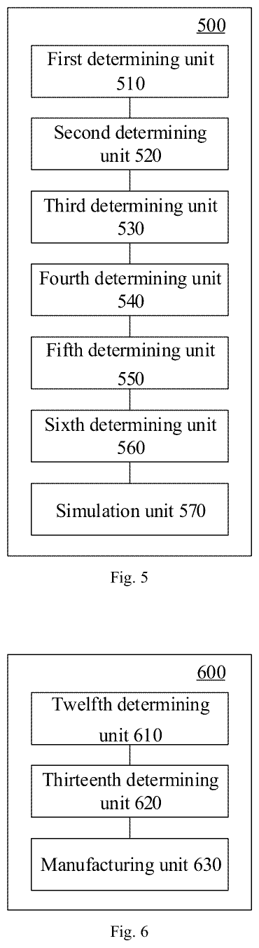

According to an embodiment of the present disclosure, a superconducting quantum chip design apparatus is further provided. A superconducting quantum chip includes a reading line, a first number of quantum bits corresponding to the reading line, and pairs of reading cavities and filters respectively corresponding to the quantum bits. As shown in FIG. 5, the apparatus 500 includes: a first determining unit 510, configured to determine a frequency range of a reading device, a first quality factor corresponding to the first number of reading cavities, and a second quality factor corresponding to the first number of filters, wherein the reading device is used for performing a reading operation on the first number of quantum bits through the reading line; a second determining unit 520, configured to determine a first frequency range corresponding to the first number of reading cavities and a second frequency range corresponding to the first number of filters based on the frequency range of the reading device; a third determining unit 530, configured to determine a frequency of each reading cavity based on the first frequency range and the first quality factor; a fourth determining unit 540, configured to determine a frequency of each filter based on the second frequency range and the second quality factor; a fifth determining unit 550, configured to determine a length of each reading cavity and a length of each filter respectively, such that a frequency difference between the frequency of each reading cavity as well as the frequency of each filter and a determined corresponding frequency does not exceed a first threshold; a sixth determining unit 560, configured to determine a spacing and a coupling length between the pair of reading cavity and filter corresponding to each quantum bit respectively, such that a difference value between the quality factor of each reading cavity and the first quality factor does not exceed a second threshold, and a difference value between the quality factor of each filter and the second quality factor does not exceed a third threshold; and a simulation unit 570, configured to perform simulation verification on a layout of the superconducting quantum chip based on the determined respective lengths of the reading cavities and the filters, the spacing and the coupling length.

Here, the operation of the above units 510-570 of the superconducting quantum chip design apparatus 500 is similar to the operation of steps 110-170 described above, and will not be repeated here.

According to an embodiment of the present disclosure, as shown in FIG. 6, a superconducting quantum chip manufacturing apparatus 600 is provided, including: a twelfth determining unit 610, configured to determine a first number of quantum bits, a pair of reading cavity and filter respectively corresponding to each quantum bit, a reading line and a control line; a thirteenth determining unit 620, configured to determine respective parameters of the pair of reading cavity and filter respectively corresponding to each quantum bit, wherein the parameters include a length of the reading cavity, a length of the filter, a spacing between the reading cavity and the filter, and a coupling length between the reading cavity and the filter; and a manufacturing unit 630, configured to form a superconducting quantum chip based on the first number of quantum bits, the pair of reading cavity and filter respectively corresponding to each quantum bit, the respective parameters of the pair of reading cavity and filter, the reading line and the control line. The parameters are determined according to the method described in any one of the above embodiments.

According to embodiments of the present disclosure, an electronic device, a readable storage medium and a computer program product are further provided.

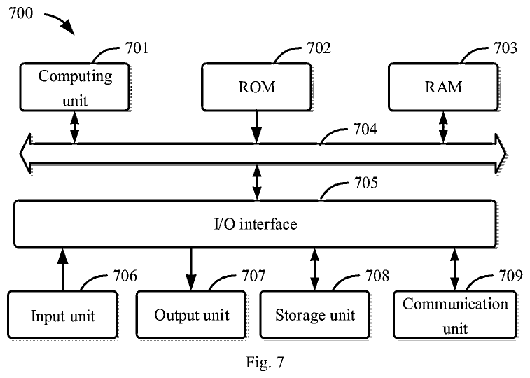

Referring to FIG. 7, a structural block diagram of the electronic device 700 which can serve as a server or a client of the present disclosure will now be described, which is an example of a hardware device capable of being applied to all aspects of the present disclosure. The electronic device aims to express various forms of digital-electronic computer devices, such as a laptop computer, a desk computer, a work bench, a personal digital assistant, a server, a blade server, a mainframe computer and other proper computers. The electronic device may further express various forms of mobile apparatuses, such as a personal digital assistant, a cellular phone, an intelligent phone, a wearable device and other similar computing apparatuses. Parts shown herein, their connection and relations, and their functions only serve as an example, and are not intended to limit implementation of the present disclosure described and/or required herein.

As shown in FIG. 7, the electronic device 700 includes a computing unit 701, which may execute various proper motions and processing according to a computer program stored in a read-only memory (ROM) 702 or a computer program loaded from a storing unit 708 to a random access memory (RAM) 703. In the RAM 703, various programs and data required by an operation of the electronic device 700 may further be stored. The computing unit 701, the ROM 702 and the RAM 703 are connected with one another through a bus 704. An input/output (I/O) interface 705 is also connected to the bus 704.

A plurality of parts in the electronic device 700 are connected to the I/O interface 705, and include: an input unit 706, an output unit 707, the storing unit 708 and a communication unit 709. The input unit 706 may be any type of device capable of inputting information to the electronic device 700, the input unit 706 may receive input digital or character information, generates key signal input relevant to user setting and/or functional control of the electronic device, and may include but is not limited to a mouse, a keyboard, a touch screen, a trackpad, a trackball, an operating lever, a microphone and/or a remote control. The output unit 707 may be any type of device capable of presenting information, and may include but is not limited to a display, a loudspeaker, a video/audio output terminal, a vibrator and/or a printer. The storing unit 708 may include but is not limited to a magnetic disc and an optical disc. The communication unit 709 allows the electronic device 700 to exchange information/data with other devices through a computer network such as Internet and/or various telecommunication networks, and may include but is not limited to a modem, a network card, an infrared communication device, a wireless communication transceiver and/or a chip set, such as a Bluetooth™ device, a 802.11 device, a WiFi device, a WiMax device, a cellular communication device and/or analogues.

The computing unit 701 may be various general and/or dedicated processing components with processing and computing capabilities. Some examples of the computing unit 701 include but are not limited to a central processing unit (CPU), a graphic processing unit (GPU), various dedicated artificial intelligence (AI) computing chips, various computing units running a machine learning model algorithm, a digital signal processor (DSP), and any proper processor, controller, microcontroller, etc. The computing unit 701 executes all the methods and processing described above, such as the method 100 or 400. For example, in some embodiments, the method 100 or 400 may be implemented as a computer software program, which is tangibly contained in a machine readable medium, such as the storing unit 708. In some embodiments, part or all of the computer program may be loaded into and/or mounted onto the electronic device 700 via the ROM 702 and/or the communication unit 709. When the computer program is loaded to the RAM 703 and executed by the computing unit 701, one or more steps of the method 100 or 400 described above may be executed. Alternatively, in other embodiments, the computing unit 701 may be configured to execute the method 100 or 400 through any other proper modes (for example, by means of firmware).

Various implementations of the systems and technologies described above in this disclosure may be implemented in a digital electronic circuit system, an integrated circuit system, a field programmable gate array (FPGA), an application specific integrated circuit (ASIC), an application specific standard part (ASSP), a system on chip (SOC), a complex programmable logic device (CPLD), computer hardware, firmware, software and/or their combinations. These various implementations may include: being implemented in one or more computer programs, wherein the one or more computer programs may be executed and/or interpreted on a programmable system including at least one programmable processor, and the programmable processor may be a special-purpose or general-purpose programmable processor, and may receive data and instructions from a storage system, at least one input apparatus, and at least one output apparatus, and transmit the data and the instructions to the storage system, the at least one input apparatus, and the at least one output apparatus.

Program codes for implementing the methods of the present disclosure may be written in any combination of one or more programming languages. These program codes may be provided to processors or controllers of a general-purpose computer, a special-purpose computer or other programmable data processing apparatuses, so that when executed by the processors or controllers, the program codes enable the functions/operations specified in the flow diagrams and/or block diagrams to be implemented. The program codes may be executed completely on a machine, partially on the machine, partially on the machine and partially on a remote machine as a separate software package, or completely on the remote machine or server.

In the context of the present disclosure, a machine readable medium may be a tangible medium that may contain or store a program for use by or in connection with an instruction execution system, apparatus or device. The machine readable medium may be a machine readable signal medium or a machine readable storage medium. The machine readable medium may include but not limited to an electronic, magnetic, optical, electromagnetic, infrared, or semiconductor system, apparatus or device, or any suitable combination of the above contents. More specific examples of the machine readable storage medium will include electrical connections based on one or more lines, a portable computer disk, a hard disk, a random access memory (RAM), a read only memory (ROM), an erasable programmable read only memory (EPROM or flash memory), an optical fiber, a portable compact disk read only memory (CD-ROM), an optical storage device, a magnetic storage device, or any suitable combination of the above contents.

In order to provide interactions with users, the systems and techniques described herein may be implemented on a computer, and the computer has: a display apparatus for displaying information to the users (e.g., a CRT (cathode ray tube) or LCD (liquid crystal display) monitor); and a keyboard and a pointing device (e.g., a mouse or trackball), through which the users may provide input to the computer. Other types of apparatuses may further be used to provide interactions with users; for example, feedback provided to the users may be any form of sensory feedback (e.g., visual feedback, auditory feedback, or tactile feedback); an input from the users may be received in any form (including acoustic input, voice input or tactile input).

The systems and techniques described herein may be implemented in a computing system including background components (e.g., as a data server), or a computing system including middleware components (e.g., an application server) or a computing system including front-end components (e.g., a user computer with a graphical user interface or a web browser through which a user may interact with the implementations of the systems and technologies described herein), or a computing system including any combination of such background components, middleware components, or front-end components. The components of the system may be interconnected by digital data communication (e.g., a communication network) in any form or medium. Examples of the communication network include: a local area network (LAN), a wide area network (WAN), the Internet and a blockchain network.

A computer system may include a client and a server. The client and the server are generally away from each other and usually interact through a communication network. A relationship of the client and the server is generated through computer programs run on a corresponding computer and mutually having a client-server relationship. The server may be a cloud server or a server of a distributed system, or a server in combination with a blockchain.

It should be understood that various forms of flows shown above may be used to reorder, increase or delete the steps. For example, all the steps recorded in the present disclosure may be executed in parallel, and may also be executed sequentially or in different sequences, as long as the expected result of the technical solution disclosed by the present disclosure may be implemented, which is not limited herein.

Although the embodiments or examples of the present disclosure have been described with reference to the accompanying drawings, it should be understood that the above method, system and device is only an exemplary embodiment or an example, and the scope of the present disclosure is not limited by these embodiments or examples, but only limited by the authorized claims and the equivalent scope thereof. Various elements in the embodiments or the examples may be omitted or may be replaced with their equivalent elements. In addition, all the steps may be executed through the sequence different from that described in the present disclosure. Further, various elements in the embodiments or the examples may be combined in various modes. It is important that with evolution of the technology, many elements described here may be replaced with the equivalent element appearing after the present disclosure.

What is claimed is:

1. A computer-implemented method for designing a superconducting quantum chip, the method comprising:
determining a frequency range of a reading device, wherein a first quality factor corresponds to a first number of reading cavities, and a second quality factor corresponds to the first number of filters, wherein the superconducting quantum chip comprises a reading line, wherein a first number of quantum bits corresponds to the reading line, the first number of reading cavities, and a first number of filters, wherein each quantum bit of the first number of quantum bits corresponds to a pair of a reading cavity and a filter, and wherein the reading device is configured to perform a reading operation on the first number of quantum bits through the reading line;
determining a first frequency range corresponding to the first number of reading cavities and a second frequency range corresponding to the first number of filters based on the frequency range of the reading device;
determining a frequency of each reading cavity of the first number of reading cavities based on the first frequency range and the first quality factor;
determining a frequency of each filter of the first number of filters based on the second frequency range and the second quality factor;
determining a length of each reading cavity of the first number of reading cavities and a length of each filter of the first number of filters, respectively, wherein a frequency difference between a frequency of each reading cavity and a corresponding frequency determined based on the first frequency range and the first quality factor and a frequency difference between a frequency of each filter and a corresponding frequency determined based on the second frequency range and the second quality factor do not exceed a first threshold;
for each quantum bit of the first number of quantum bits, determining a spacing and a coupling length between the pair of the reading cavity and the filter corresponding to the quantum bit in such a manner that a difference value between a quality factor of the reading cavity and the first quality factor does not exceed a second threshold and a difference value between a quality factor of the filter and the second quality factor does not exceed a third threshold; and
performing a simulation verification on a layout of the superconducting quantum chip based on the determined respective lengths of the reading cavities in the first number of reading cavities, the determined respective lengths of the filters in the first number of filters, and the determined respective spacing and coupling length between the pair of the reading cavity and the filter corresponding to each quantum bit.

2. The method according to claim 1, wherein the performing the simulation verification on the layout of the superconducting quantum chip comprises:
performing the simulation verification on the layout of the superconducting quantum chip to adjust the length of each reading cavity and the length of each filter in such a manner that the frequency difference between the frequency of each reading cavity and a corresponding frequency determined based on the first frequency range and the first quality factor and the frequency difference between the frequency of each filter and a corresponding frequency determined based on the second frequency range and the second quality factor do not exceed a fourth threshold.

3. The method according to claim 1, wherein the determining the first frequency range corresponding to the first number of reading cavities and the second frequency range corresponding to the first number of filters comprises:
determining the first frequency range and the second frequency range in such a manner that each of the first frequency range and the second frequency range is close to the frequency range of the reading device within a preset error range.

4. The method according to claim 1, wherein the determining the first frequency range corresponding to the first number of reading cavities and the second frequency range corresponding to the first number of filters comprises:
determining a coupling strength between each quantum bit and each reading cavity, and a reading frequency of each quantum bit; and
determining the first frequency range and the second frequency range based on the coupling strength and the reading frequency.

5. The method according to claim 1,
wherein the superconducting quantum chip comprises a plurality of the quantum bits;
wherein the determining the frequency of each reading cavity of the first number of reading cavities comprises: respectively determining a frequency interval between adjacent reading cavities in the first number of reading cavities based on the first frequency range and the quality factor of each reading cavity, to determine the frequency of each reading cavity based on the frequency interval between the first number of reading cavities, and
wherein the determining the frequency of each filter of the first number of filters comprises: respectively determining a frequency interval between adjacent filters in the first number of filters based on the second frequency range and the quality factor of each filter, to determine the frequency of each filter based on the frequency interval between the first number of filters.

6. The method according to claim 5, wherein the frequency interval between the adjacent reading cavities in the first number of reading cavities is greater than a maximum bandwidth of the first number of reading cavities, and the frequency interval between the adjacent filters in the first number of filters is greater than a maximum bandwidth of the first number of filters.

7. The method according to claim 2, wherein the fourth threshold is smaller than the first threshold.

8. The method according to claim 1, further comprising:
forming a superconducting quantum chip based on the determined respective lengths of the reading cavities in the first number of reading cavities, the determined respective lengths of the filters in the first number of filters, and the determined respective spacing and coupling length between the pair of the reading cavity and the filter corresponding to each quantum bit after simulation verification.

9. An electronic device for designing a superconducting quantum chip, the electronic device comprising:
a memory storing one or more programs configured to be executed by one or more processors, the one or more programs including instructions for causing the electronic device to perform operations comprising:
determining a frequency range of a reading device, wherein a first quality factor corresponds to a first number of reading cavities, and a second quality factor corresponds to the first number of filters, wherein the superconducting quantum chip comprises a reading line, wherein a first number of quantum bits corresponds to the reading line, the first number of reading cavities, and a first number of filters, wherein each quantum bit of the first number of quantum bits corresponds to a pair of a reading cavity and a filter, and wherein the reading device is configured to perform a reading operation on the first number of quantum bits through the reading line;
determining a first frequency range corresponding to the first number of reading cavities and a second frequency range corresponding to the first number of filters based on the frequency range of the reading device;
determining a frequency of each reading cavity of the first number of reading cavities based on the first frequency range and the first quality factor;
determining a frequency of each filter of the first number of filters based on the second frequency range and the second quality factor;
determining a length of each reading cavity of the first number of reading cavities and a length of each filter of the first number of filters, respectively, wherein a frequency difference between a frequency of each reading cavity and a corresponding frequency determined based on the first frequency range and the first quality factor and a frequency difference between a frequency of each filter and a corresponding frequency determined based on the second frequency range and the second quality facto do not exceed a first threshold;
for each quantum bit of the first number of quantum bits, determining a spacing and a coupling length between the pair of the reading cavity and the filter corresponding to the quantum bit in such a manner that a difference value between a quality factor of the reading cavity and the first quality factor does not exceed a second threshold and a difference value between a quality factor of the filter and the second quality factor does not exceed a third threshold; and
performing a simulation verification on a layout of the superconducting quantum chip based on the determined respective lengths of the reading cavities in the first number of reading cavities, the determined respective lengths of the filters in the first number of filters, and the determined respective spacing and coupling length between the pair of the reading cavity and the filter corresponding to each quantum bit.

10. The electronic device according to claim 9, wherein the performing the simulation verification on the layout of the superconducting quantum chip comprises:
performing the simulation verification on the layout of the superconducting quantum chip to adjust the length of each reading cavity and the length of each filter in such a manner that the frequency difference between the frequency of each reading cavity and a corresponding frequency determined based on the first frequency range and the first quality factor and the frequency difference between the frequency of each filter and a corresponding frequency determined based on the second frequency range and the second quality factor do not exceed a first threshold.

11. The electronic device according to claim 9, wherein the determining the first frequency range corresponding to the first number of reading cavities and the second frequency range corresponding to the first number of filters comprises:
determining the first frequency range and the second frequency range in such a manner that each of the first frequency range and the second frequency range is close to the frequency range of the reading device within a preset error range.

12. The electronic device according to claim 9, wherein the determining the first frequency range corresponding to the first number of reading cavities and the second frequency range corresponding to the first number of filters comprises:
determining a coupling strength between each quantum bit and each reading cavity, and a reading frequency of each quantum bit; and
determining the first frequency range and the second frequency range based on the coupling strength and the reading frequency.

13. The electronic device according to claim 9,
wherein the superconducting quantum chip comprises a plurality of the quantum bits; wherein the determining the frequency of each reading cavity of the first number of reading cavities comprises: respectively determining a frequency interval between adjacent reading cavities in the first number of reading cavities based on the first frequency range and the quality factor of each reading cavity, to determine the frequency of each reading cavity based on the frequency interval between the first number of reading cavities, and
wherein the determining the frequency of each filter of the first number of filters comprises: respectively determining a frequency interval between adjacent filters in the first number of filters based on the second frequency range and the quality factor of each filter, to determine the frequency of each filter based on the frequency interval between the first number of filters.

14. The electronic device according to claim 13, wherein the frequency interval between the adjacent reading cavities in the first number of reading cavities is greater than a maximum bandwidth of the first number of reading cavities, and the frequency interval between the adjacent filters in the first number of filters is greater than a maximum bandwidth of the first number of filters.

15. The electronic device according to claim 10, wherein the fourth threshold is smaller than the first threshold.

16. The electronic device according to claim 9, the operations further comprising:
forming a superconducting quantum chip based on the determined respective lengths of the reading cavities in the first number of reading cavities, the determined respective lengths of the filters in the first number of filters, and the determined respective spacing and coupling length between the pair of the reading cavity and the filter corresponding to each quantum bit after simulation verification.

17. A non-transitory computer-readable storage medium that stores one or more programs comprising instructions that, when executed by one or more processors of a computing device, cause the computing device to implement operations comprising:
determining a frequency range of a reading device, wherein a first quality factor corresponds to a first number of reading cavities, and a second quality factor corresponds to the first number of filters, wherein the superconducting quantum chip comprises a reading line, wherein a first number of quantum bits corresponds to the reading line, the first number of reading cavities, and a first number of filters, wherein each quantum bit of the first number of quantum bits corresponds to a pair of a reading cavity and a filter, and wherein the reading device is configured to perform a reading operation on the first number of quantum bits through the reading line;
determining a first frequency range corresponding to the first number of reading cavities and a second frequency range corresponding to the first number of filters based on the frequency range of the reading device;
determining a frequency of each reading cavity of the first number of reading cavities based on the first frequency range and the first quality factor;
determining a frequency of each filter of the first number of filters based on the second frequency range and the second quality factor;
determining a length of each reading cavity of the first number of reading cavities and a length of each filter of the first number of filters, respectively, wherein a frequency difference between a frequency of each reading cavity and a corresponding frequency determined based on the first frequency range and the first quality factor and a frequency difference between a frequency of each filter and a corresponding frequency determined based on the second frequency range and the second quality factor do not exceed a first threshold;
for each quantum bit of the first number of quantum bits, determining a spacing and a coupling length between the pair of the reading cavity and the filter corresponding to the quantum bit in such a manner that a difference value between a quality factor of the reading cavity and the first quality factor does not exceed a second threshold and a difference value between a quality factor of the filter and the second quality factor does not exceed a third threshold; and
performing a simulation verification on a layout of the superconducting quantum chip based on the determined respective lengths of the reading cavities in the first number of reading cavities, the determined respective lengths of the filters in the first number of filters, and the determined respective spacing and coupling length between the pair of the reading cavity and the filter corresponding to each quantum bit.

18. The non-transitory computer-readable storage medium according to claim 17, wherein the performing the simulation verification on the layout of the superconducting quantum chip comprises:
performing the simulation verification on the layout of the superconducting quantum chip to adjust the length of each reading cavity and the length of each filter in such a manner that the frequency difference between the frequency of each reading cavity and a corresponding frequency determined based on the first frequency range and the first quality factor and the frequency difference between the frequency of each filter and a corresponding frequency determined based on the second frequency range and the second quality factor do not exceed a fourth threshold.

19. The non-transitory computer-readable storage medium according to claim 17, wherein the determining the first frequency range corresponding to the first number of reading cavities and the second frequency range corresponding to the first number of filters comprises:
determining the first frequency range and the second frequency range in such a manner that each of the first frequency range and the second frequency range is close to the frequency range of the reading device within a preset error range.

20. The non-transitory computer-readable storage medium according to claim 17, wherein the determining the first frequency range corresponding to the first number of reading cavities and the second frequency range corresponding to the first number of filters comprises:
determining a coupling strength between each quantum bit and each reading cavity, and a reading frequency of each quantum bit; and
determining the first frequency range and the second frequency range based on the coupling strength and the reading frequency.
